(19) United States
(12) Patent Application Publication
(10) Pub. No.: US 2024/0146257 A1
(43) Pub. Date: May 2, 2024

(54) RADIO FREQUENCY POWER AMPLIFIER MODULE USING CAVITY AND SUBMODULE TECHNOLOGIES

(71) Applicant: Avago Technologies International Sales Pte. Limited, Singapore (SG)

(72) Inventors: Wangmyong WOO, San Jose, CA (US); Chang Kyu Choi, Fremont, CA (US); Wei-Shun Wang, Palo Alto, CA (US); Ricardo Javier Torres, San Jose, CA (US)

(21) Appl. No.: 17/978,201

(22) Filed: Oct. 31, 2022

(51) Int. Cl. H03F 3/195; H03F 3/24

(52) U.S. Cl. CPC H03F 3/195; H03F 3/245; H03F 2200/372; H03F 2200/451

(57) ABSTRACT

Aspects of the subject technology provide miniaturization and improved power dissipation for communication systems that include a radio frequency power amplifier. In aspects, a radio frequency power amplifier may be mounted inside a cavity in a primary printed circuit board. Circuits related the power amplifier, such as output matching circuits, biasing circuits, and/or passive components, may be mounted on submodule printed circuit board that itself is mounted to the primary printed circuit board in a stacked configuration above the power amplifier and the cavity containing the power amplifier.

### TECHNICAL FIELD

The present description relates generally to radio frequency transmitters and electric power amplifiers.

### BACKGROUND

Transmitters in modern wireless communication devices generally include a radio frequency (RF) power amplifier (PA) in the transmitter chain to convert a low-power RF signal into a high-power RF signal for driving an antenna of the wireless communication device.

### BRIEF DESCRIPTION OF THE DRAWINGS

Certain features of the subject technology are set forth in the appended claims.

However, for purpose of explanation, several implementations of the subject technology are set forth in the following figures.

FIG. 1 illustrates a cross-sectional view of an electronic device according to one approach.

FIG. 2 illustrates a cross-sectional view of an electronic device according to one approach.

FIG. 3A is a schematic diagram of an electronic device according to aspects of this disclosure.

FIG. 3B illustrates a cross-sectional view of an electronic device according to aspects of this disclosure.

FIG. 3C illustrates a top view of the submodule PCB of FIG. 3B, according to aspects of this disclosure.

FIGS. 4A, 4B, and 4C illustrate a manufacturing process according to aspects of this disclosure.

FIG. 5 illustrates a cross-sectional view of an electronic device according to aspects of this disclosure.

FIG. 6 illustrates a cross-sectional view of an electronic device according to aspects of this disclosure.

FIG. 7 illustrates a cross-sectional view of an electronic device according to aspects of this disclosure.

FIG. 8 illustrates a cross-sectional view of an electronic device according to aspects of this disclosure.

FIGS. 9A and 9B illustrate a cross-sectional view of electronic devices according to aspects of this disclosure.

FIG. 10A is a schematic diagram including a single-ended output matching circuit according to aspects of this disclosure.

FIG. 10B is a schematic diagram including a differential output matching circuit according to aspects of this disclosure.

FIG. 11 illustrates a variety conductive joint shapes according to aspects of this disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

Improved aspects of radio frequency transmitters are disclosed, including physical configurations that enable miniaturization and improved high-power interconnections. In aspects, a radio frequency (RF) power amplifier (PA) may be mounted inside a cavity in a first printed circuit board (PCB). Circuits related to the power amplifier, such as output matching circuits, biasing circuits, and/or passive electrical components, may be mounted on a second PCB that itself is mounted to the first PCB in a stacked configuration above the power amplifier and the cavity containing the power amplifier. Mounting some electrical components above the power amplifier may reduce the surface area required to fit components on the first PCB, which may result in a smaller PCB and an overall smaller communications device containing the first PCB. Furthermore, by mounting the power amplifier inside a cavity and below a first surface of the first PCB, the physical distance between the power amplifier and a device mounted to a second surface opposite the first surface of the first PCB may be reduced. This reduced distance may enable an improved high-power interconnection between the power amplifier and the second surface mounted device, including a shorter thermal contact length and better heat dissipation.

The first PCB may be a primary PCB and the second PCB may be a submodule PCB. In one aspect, a primary PCB may be the PCB with cavity which is covered by a submodule PCB. In another aspect, a primary PCB may be larger than the submodule PCB, or the primary PCB may hold a larger number of, or larger size of, electronic components as compared to the submodule PCB.

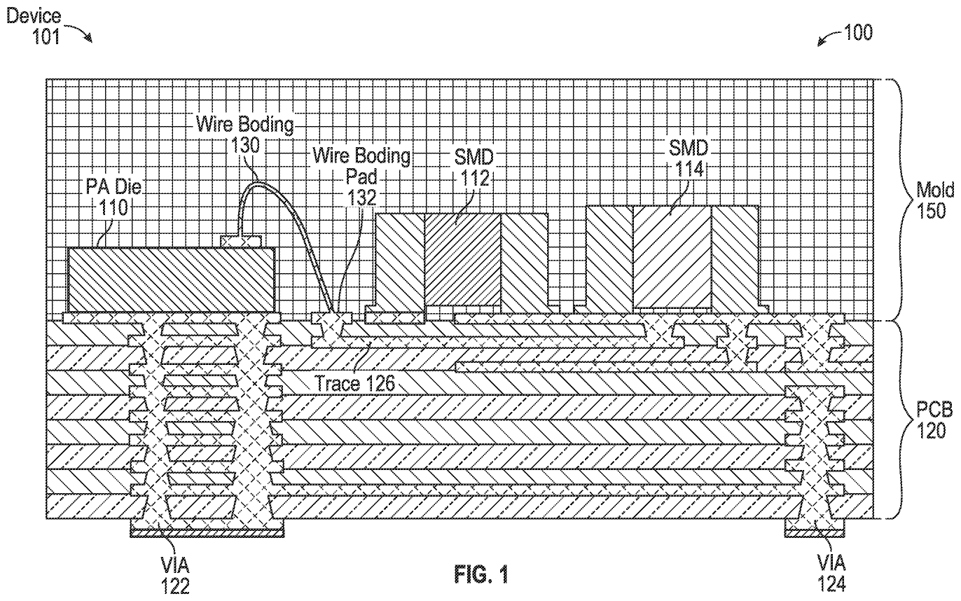

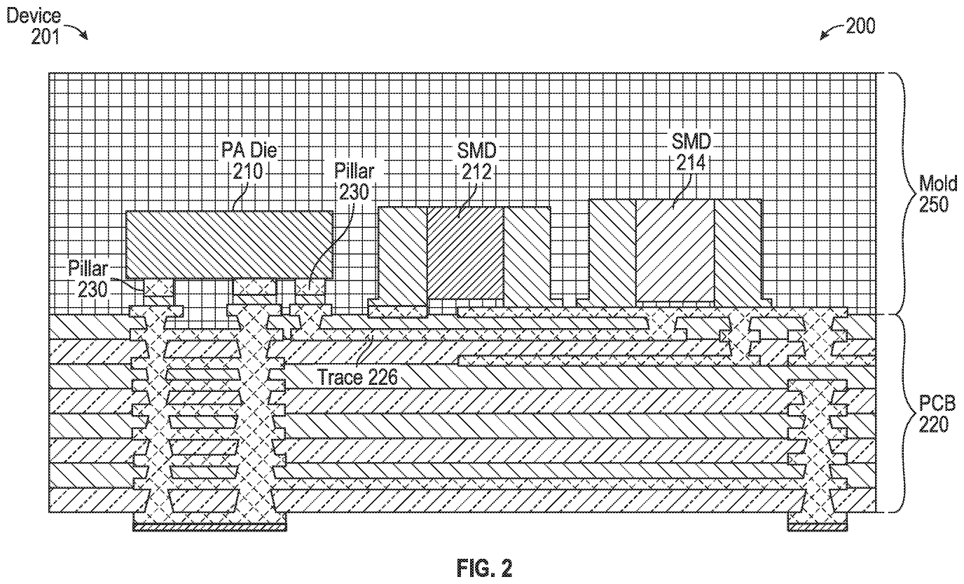

FIGS. 1 and 2 depict some approaches for power amplifier interconnections. FIG. 1 illustrates a cross-sectional view 100 of an electronic device 101. Electronic device 100 including a power amplifier die 110 is mounted to a top surface of PCB 120, and may be mounted, for example, with epoxy die attach adhesive. Power amplifier die 110 is electrically connected to surface-mount devices 112, 114 through an electrical connection path including wire bonding 130 between a top surface of power amplifier die 110 and a wire bonding pad 132 on the top surface of PCB 120, vertical vias, and trace 126. Surface-mount devices 112, 114 may include a bias circuit and an output matching circuit for the power amplifier die 110.

FIG. 2 illustrates a cross-sectional view 200 of an electronic device 201, including a power amplifier die 210 mounted to top surface of PCB 220. In contrast with device 101 of FIG. 1, power amplifier die 210 of device 201 is mounted to PCB 220 via pillars 230, which may be copper pillars. Pillars 230 may allow electrical connection between power amplifier die 210 to surface mounted devices 212, 214 via trace 226 without wire bonding. As shown in FIGS. 1-2, the designs of both devices 101, 201 require enough surface area on a PCB to mount a power amplifier and any related surface-mount devices such as a bias circuit and an output matching circuit for the power amplifier.

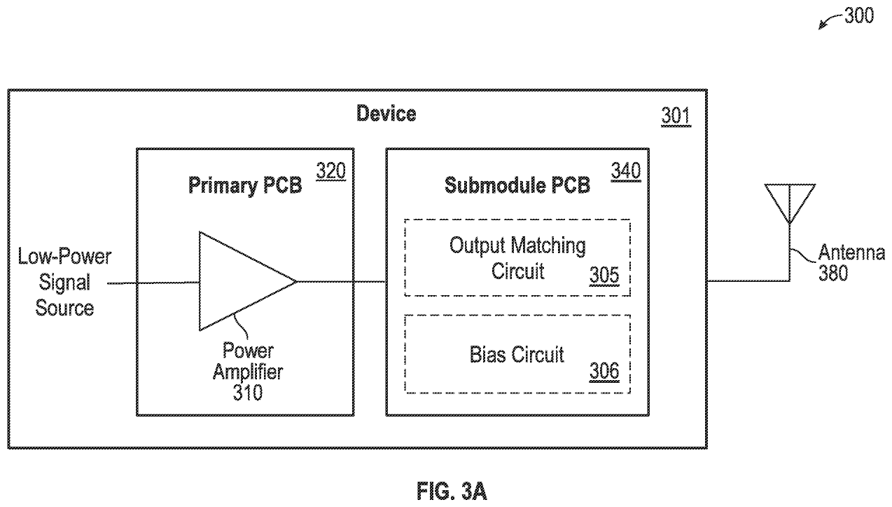

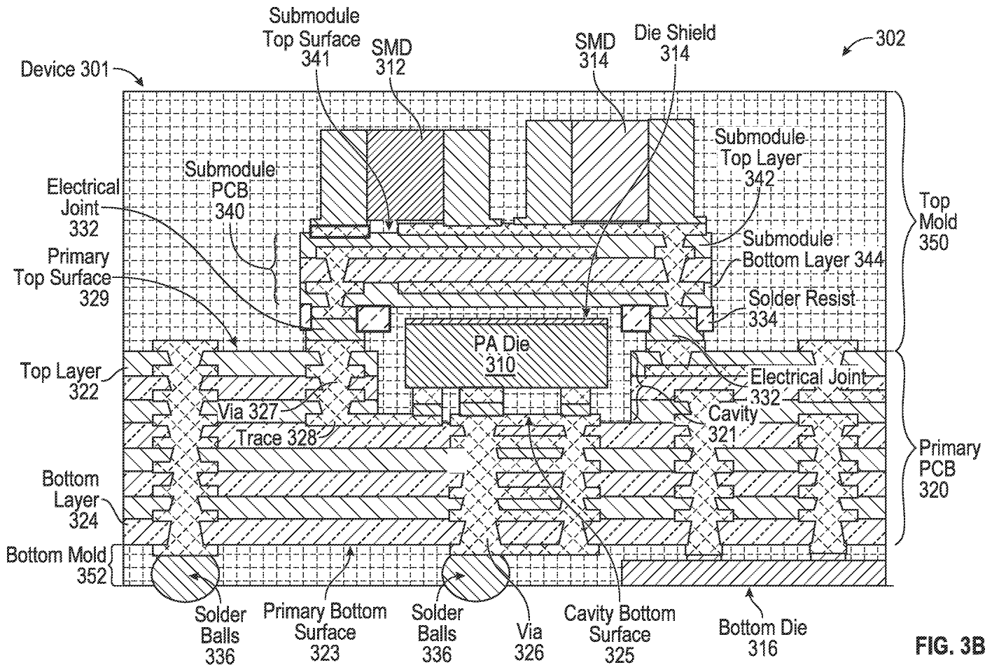

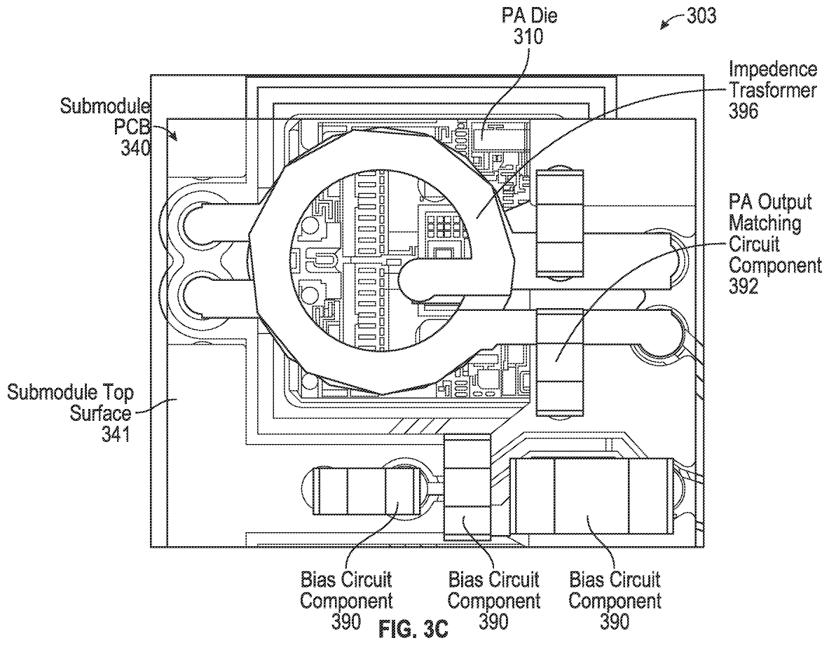

FIG. 3A is a schematic diagram 300 of an electronic device 301 according to aspects of this disclosure and according to aspects of the subject technology. Schematic diagram 300 includes an electronic device 301, having power amplifier 310 in a first PCB (labeled the primary PCB 320 in the figures), and a second PCB (labeled submodule PCB 340). Submodule PCB 340 may include optional components such as an output matching circuit 305 for power amplifier 310, and/or a bias circuit for power amplifier 306. In aspects, power amplifier 310 may be configured as a radio frequency power amplifier that amplifies a lower-power communication signal into a high-power communications signal. A transmitter chain for device 301 may include regulating the high-power output signal by bias circuit 306 and matching it to a load such as optional antenna 380 by output matching circuit 305.

FIG. 3B illustrates a cross-sectional view 302 of electronic device 301 according to aspects of this disclosure. As compared to devices 101, 201, electronic device 301 may provide improvements such as better miniaturization and heat dissipation, as explained further below. Electronic device 301 includes a power amplifier (PA) die 310 mounted in a cavity 321 formed in the top of a first PCB, primary PCB 320. A second PCB, submodule PCB 340, is mounted above power amplifier die 310 and above cavity 321 at electrical joints 332 onto a first surface of primary PCB 320, the primary top surface 329.

In an aspect, electric components, such as surface-mount devices 312, 314 may be mounted on submodule 340 that might otherwise be mounted directly to primary PCB 320. For example, by mounting surface-mount devices (SMDs) 312, 314 on submodule top surface 341 and above power amplifier die 310 instead of mounting on primary top surface 329, a size of the primary PCB may be reduced due to reduced spatial area requirements on primary top surface 329 to fit all necessary components. For example, a matching circuit, a bias circuit, and/or related passive components for power amplifier 310, which may be best located near power amplifier 310, may be mounted on submodule PCB 340 and above power amplifier 310. Such a reduced surface area requirement for a primary PCB may enable miniaturization of a communications system containing electronic device 301.

In another aspect, mounting power amplifier 310 in cavity 321 may result in improved heat dissipation due to a shortened thermal contact length from power amplifier die 310 to lower layers of primary PCB 320. For example, power amplifier 310 may be mounted to an inner surface of cavity 321 such as cavity bottom surface 325. Heat generated by power amplifier die 310 may dissipate through a metal layer at or near the bottom of primary PCB 320 by traveling through fewer layers of the primary PCB as would be required if power amplifier 310 were mounted on primary top surface 329. In an aspect, a thermally conductive element, such as a metallic via 326, may assist in drawing heat from power amplifier die 310 down toward the opposite side of primary PCB 320. Some implementations may benefit from such a shortened thermal contact length by mounting a device in cavity 321 without including a stacked submodule such as submodule PCB 340.

Electronic device 301 also includes several optional aspects. In some optional aspects, power amplifier die 310 is mounted at joints to a cavity bottom surface 325 of cavity 321, and power amplifier die 310 includes a die shield 314 on a backside of the die, where the backside is opposite the joints on the cavity bottom surface 325. A die shield may be, for example, formed of a conductive material such as gold (Au). Shield 314, may be an electromagnetic shield that functions to limit electromagnetic coupling between power amplifier 310 and a matching component, such as an impedance transformer 396, embedded in the submodule PCB 340. Instead or in addition, shield 314 may function to strengthen packaging of power amplifier die 310 to help prevent cracking or other mechanical damage during a manufacturing processes such as those using a surface-mount technology (SMT) pick-and-place machine.

In other optional aspects, primary PCB 320 may be a multi-layer board having a plurality of insulating layers alternating with conductive traces between the insulating layers, and having one or more conductive vias forming an electrical connection path connecting traces and joints across layers. Insulating layers of a PCB may be, for example, a series of one or more layers formed of an electrically non-conductive substrate. As depicted in FIG. 3B, primary PCB 320 includes top layer 322 and bottom layer 324. A top surface of top layer 322 forms at least a portion of primary top surface 329 of the primary PCB, and a bottom surface of bottom layer 324 forms at least a portion of primary bottom surface 323 of the primary PCB. Cavity 321 is three PCB layers deep, giving cavity 321 a depth from the primary PCB top surface 329 to the cavity bottom surface 325 equivalent to the thickness of the top three PCB layers. In other implementations, a power amplifier may be mounted in a PCB cavity of varying depth. For example, a power amplifier may be mounted in any cavity with exposed traces and/or conductive vias, including cavities with depths corresponding to the thickness of one or more PCB layers.

In an aspect, a cavity in a PCB may include any space extending into an interior of a PCB. For example, a PCB may have a cavity including an opening in an exterior surface (such as primary top surface 329) of the PCB, and extending from the opening into the interior of the PCB. In application with a multi-layer board, the cavity may extend to a variety of depths below the opening, such as less than, equal to, or greater than a thickness of one layer. In one example, a cavity in a multilayer board may have a depth substantially equivalent to the thickness of an integer number of insulating layers. In some aspects, the cavity may have sufficient depth for fully enclose electrical components (such as a power amplifier) that are mounted to a surface inside the cavity. In other aspects, a portion of a components mounted inside the cavity may extend past the opening in the PCB surface. For example, as depicted in FIG. 3B, power amplifier die 310 is mounted inside the cavity at cavity bottom surface 325, while the portion of power amplifier die 310 that include die shield 314 extends past the plane containing primary top surface 329 and out of the cavity 321. In an aspect, submodule PCB 340 may be mounted to primary PCB 320 in such a way as to create sufficient space underneath submodule PCB 340 in order to accommodate for portions of cavity mounted components (such power amplifier die 310) that may extend out of the cavity. For example, electrical joint 332, such as solder joint 532 formed from a solder ball or copper pillar 952, may create headroom under a submodule PCB for any portions of cavity mounted components that extend outside the cavity in a primary PCB.

In an aspect, mounting of components may include a mechanical coupling and/or electrical coupling, including direct and indirect coupling. For example, power amplifier die 310 may be mounted to primary PCB 320 inside cavity 321 at cavity bottom surface 325 by a solder balls that serve as both a physical coupling and an electrical coupling between power amplifier die 310 and primary PCB 320. A mechanical coupling may substantially secure a relative physical positioning between two mechanically coupled components. An electrical coupling or electrical connection may provide a path, such as one or more electrical conduit(s) in series, between the electrically coupled components for carrying electrical power and/or electrical signals. In an aspect, when a component, such as power amplifier die 310, is mounted in a cavity, the mounting elements, such as a mechanical and/or electrical joint, may be inside the cavity while some other portion of the component, such as die shield 314, may extend out of the cavity in that it extends beyond a plane formed by primary top surface 329.

An amplified output of power amplifier 310 may be electrically connected to electrical devices, such as an antenna, attached the opposite side of primary PCB. Such an electrical connection across insulating layers of the primary PCB 320 may be made with vias such as via 326. For example, power amplifier 310 may be electrically connected to bottom die 316 and/or a device attached to a solder balls 336. In one example, power amplifier die 310 may be connected by via 326 to a solder ball 336 positioned at a location on primary bottom surface 323 directly opposite the location of power amplifier die 310. Solder balls 336 may enable connection to a component that consumes the amplified output of power amplifier 310, such as antenna 380. In other aspects, electric components mounted to submodule PCB 340 may also be electrically connected to power amplifier die 310, such as via electrical joints 332, via 327, and trace 328. In an aspect, electrical joints 332 may be solder ball joints and may be surrounded by an additional mechanical joint such as solder resist 334.

In an aspect, a first mold, top mold 350, may be formed of molding material on primary top surface 329, and top mold 350 may enclose most or all of top surface 329, as well as enclosing power amplifier die 310, submodule PCB 340, and any electrical components mounted to submodule PCB 340, such as surface-mount devices 312, 314 and other passive components (not depicted in FIG. 3). Similarly, in some aspects, a second mold, bottom mold 352, may be positioned on primary bottom surface 323, which may enclose some or all of primary bottom surface 323 as well as electrical components mounted to primary bottom surface 323.

FIG. 3C illustrates a top view 303 of the submodule PCB 340 of FIG. 3B, according to aspects of this disclosure. Submodule 340 include power amplifier matching circuit components 392, impedance transformer 396, and bias circuit components 390 for power amplifier die 310, which are mounted on submodule top layer 322.

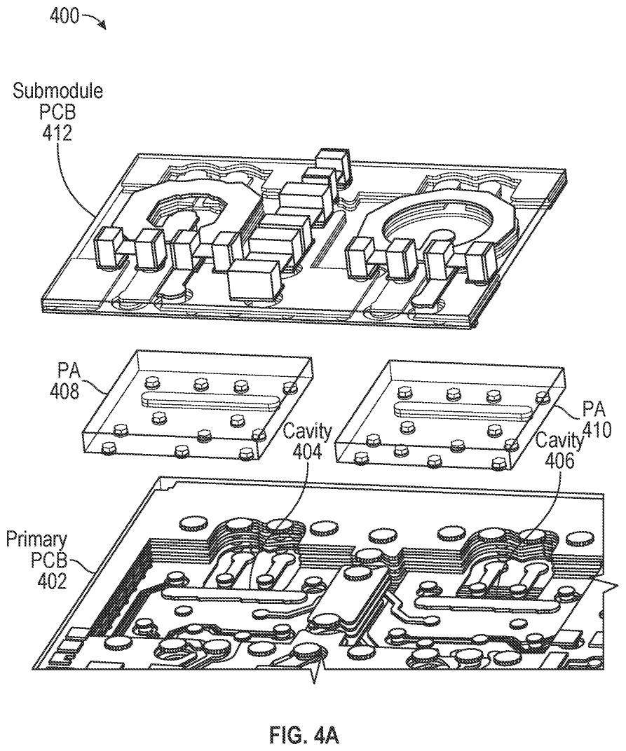

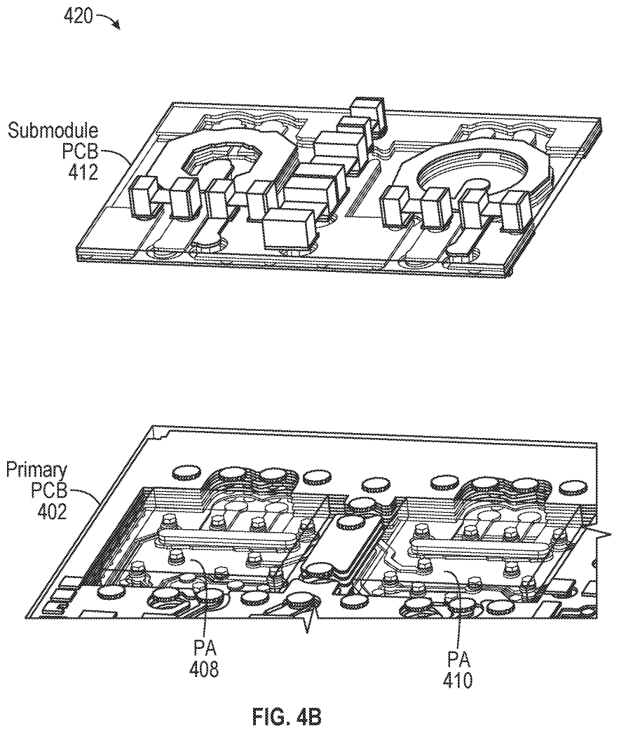

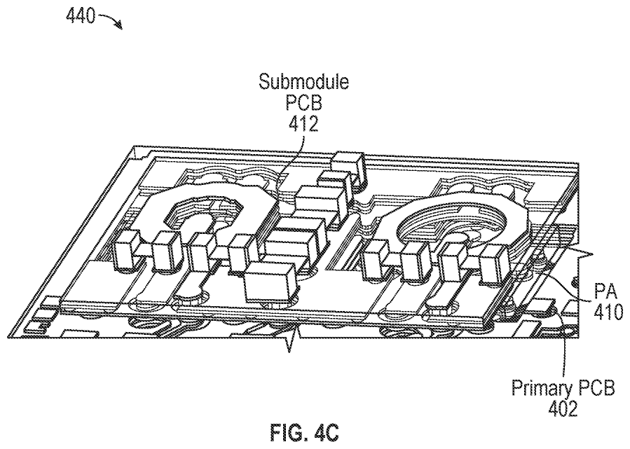

FIGS. 4A, 4B, and 4C illustrate a manufacturing process according to aspects of this disclosure. FIGS. 4A, 4B, and 4C also illustrate an example device 402 with two PCB cavities 404, 406 and two power amplifiers 408, 410 that may be covered with a single submodule PCB 412. In the manufacturing process of FIGS. 4A-C, stage 400 starts with separate device components PCBs 402, 412, and power amplifiers 408, 410. At stage 420, power amplifiers 408, 410 are electrically and mechanically mounted into corresponding cavities 404, 406 in a top surface of primary PCB 402. At stage 440, submodule PCB 412 is electrically and mechanically mounted onto the top surface of primary PCB 402 such that submodule PCB 412 substantially covers both power amplifiers 408, 410 and PCB cavities 404, 406. In an optional aspect prior to stage 400, cavities 404, 406 may be created in the primary PCB 402 by removing one or more layers from the top surface of primary PCB 402. In an alternate aspect, primary PCB 402 may have been formed originally to include cavities 404, 406.

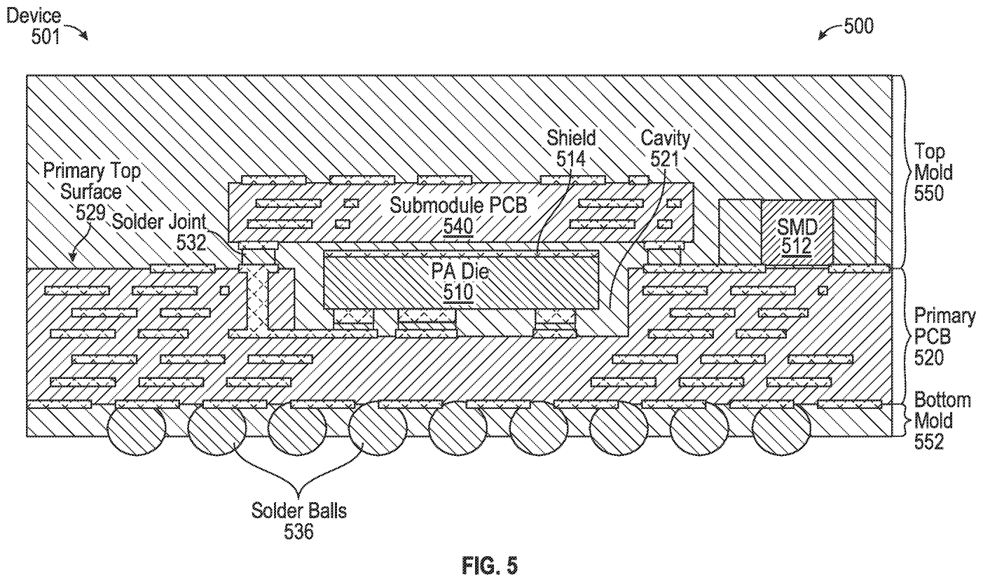

FIG. 5 illustrates a cross-sectional view 500 of a device 501 according to aspects of the subject technology. Device 501 includes multilayer primary PCB 520 mechanically and electrically coupled to multilayer submodule PCB 540 at a solder joint 532 on primary top surface 529. Power amplifier die 510 is mounted under submodule PCB 540 and inside cavity 521 formed in primary PCB 520. The power amplifier die 510 includes a shield 514 on the backside of power amplifier die 510 opposite its mounting joints to primary PCB 520. The bottom footprint of the primary PCB 520 includes an array of solder balls 536. Molding material(s), such as a compound material, may form a top mold 550 and bottom mold 552 covering the top and bottom, respectively, of primary PCB 520.

In other aspects not depicted, implementations may use a variety of types of interconnections at the bottom of primary PCB 520. For example, solder balls 536 may be arranged as a grid array of solder balls on the bottom of primary PCB 520. In other examples, the bottom of primary PCB 520 may include a grid array of copper posts, a land grid array in an organic solderability preservative finish, and/or a land grid array with solder mask-defined pads. Some implementations may mix multiple types of interconnections on the bottom of a single primary PCB.

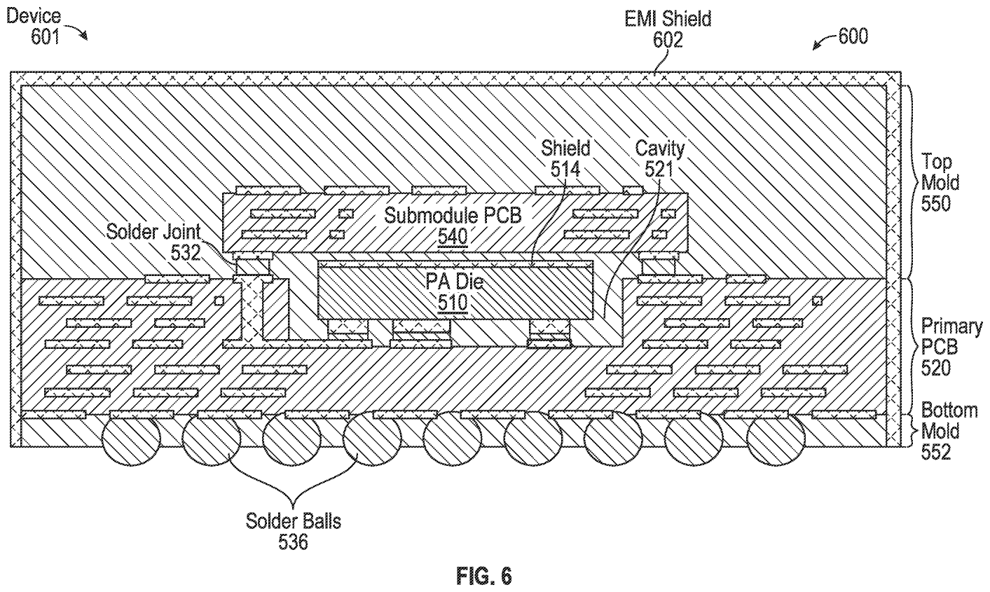

FIG. 6-9A/B illustrate variations of device 501, including variants 601, 701, 801, 901, 951. Identical element numbers in the different figures indicate similar elements of different devices.

FIG. 6 illustrates a cross-sectional view 600 of a device 601 according to aspects of the subject technology. Device 601 includes an electromagnetic interference (EMI) shield 602 covering the top and side of device 601, including sides of top mold 550, sides of primary PCB 520, and sides of bottom mold 552. In an aspect, EMI shield 602 may reduce or block interference radiated to or from device 601, and may reduce EMI coupling.

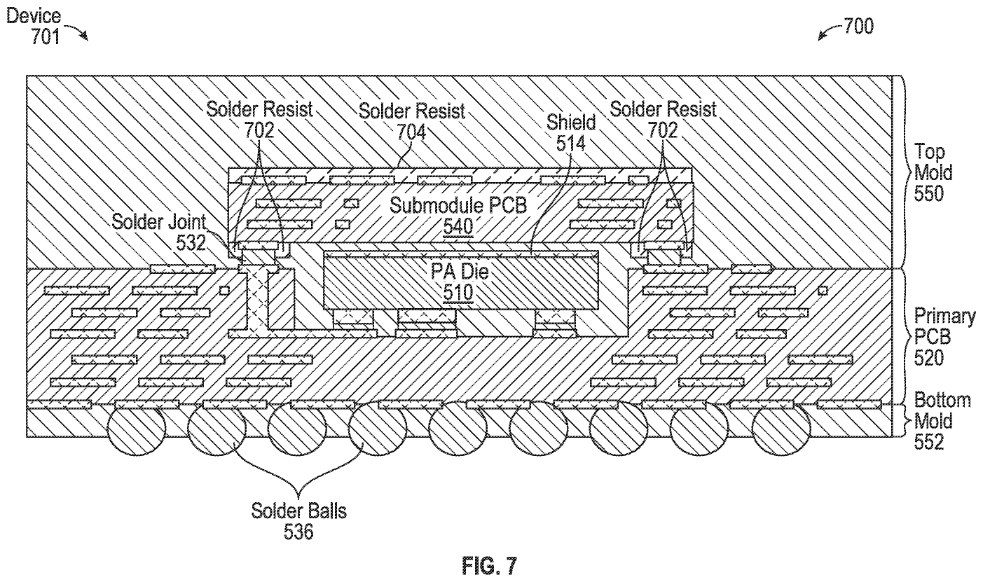

FIG. 7 illustrates a cross-sectional view 700 of a device 701 according to aspects of the subject technology. Device 701 includes a top solder resist layer 704 over the top/backside of submodule PCB 540, and a bottom solder resist layer 702 on the bottom of submodule PCB 540. In an aspect, bottom solder resist layer 702 may surround solder joints 532. In some implementations, solder resist may be applied to only the top side or only the bottom side of submodule PCB 540. In an aspect, solder resist layers 702 and/or 704 may enhance a stiffness and/or flatness of submodule PCB 540.

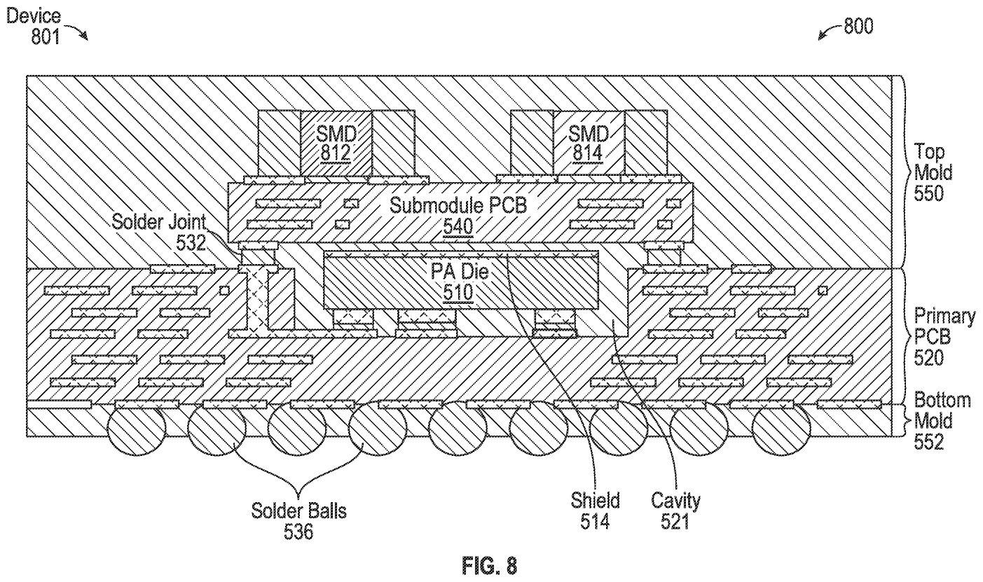

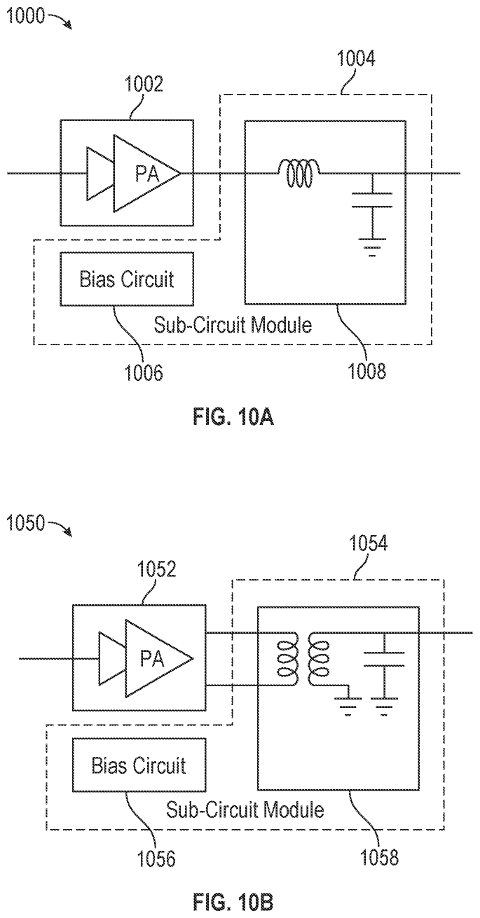

FIG. 8 illustrates a cross-sectional view 800 of a device 801 according to aspects of the subject technology. Device 801 includes surface-mount devices 812, 814 mounted to submodule PCB 540. Various electric circuit elements may be mount on and/or embedded in submodule PCB 540. Electrical circuit elements included in or on submodule PCB 540 may include, for example: a single-ended output matching circuit for power amplifier die 510 (for example, as depicted in FIG. 10A); a differential output matching for power amplifier die 510 (for example, as depicted in FIG. 10B); power amplifier bias circuit for power amplifier die 510 (for example, as depicted in FIGS. 10A or 10B); other components supporting power amplifier die 510 or for which physical proximity to power amplifier die 510 is required or beneficial; any other components that might otherwise be embedded in or mounted on primary PCB 520 including embedded passive components and surface-mount components.

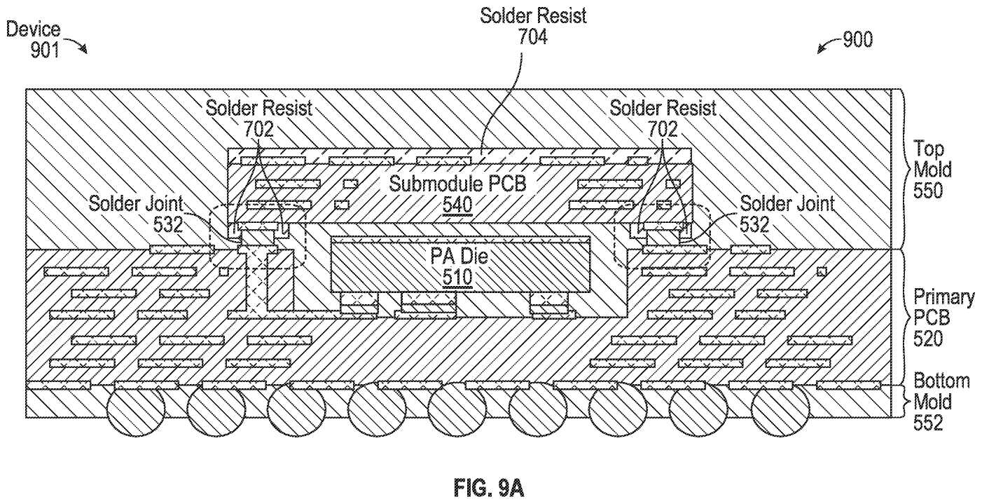

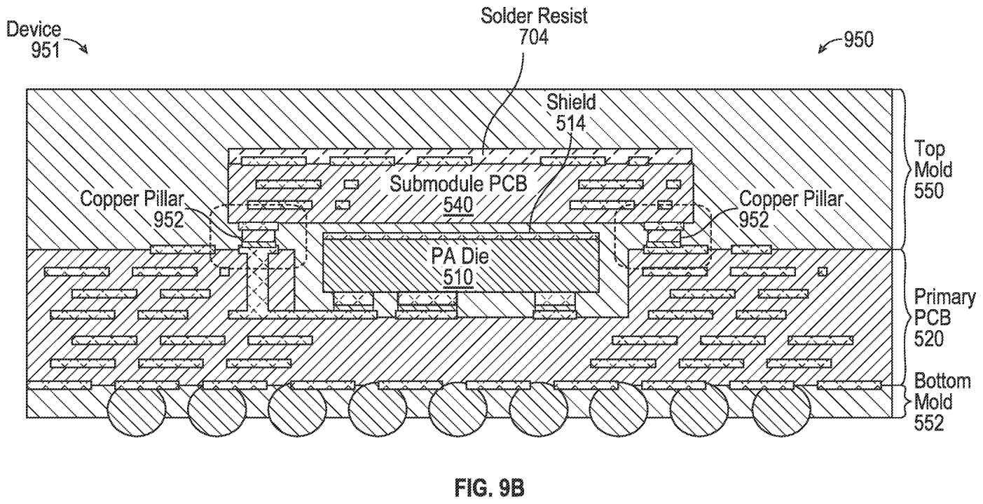

FIGS. 9A and 9B illustrate a cross-sectional views 900, 950 of electronic devices 901, 951, respectively, according to aspects of the subject technology. FIGS. 9A and 9B illustrate different techniques for mounting submodule PCB 540 to primary PCB 520. In FIG. 9A, device 901 includes a solder joint 532 and surrounding solder resist 702 which provide mechanical and electrical connection between primary PCB 520 and submodule PCB 540. In FIG. 9B, device 951 includes copper pillars 952 which provide mechanical and electrical connection between primary PCB 520 and submodule PCB 540.

FIG. 10A is a schematic diagram including a single-ended output matching circuit according to aspects of the subject technology. FIG. 10A depicts a circuitry 1000 including a power amplifier 1002 and a subcircuit module 1004 having a single-ended output matching circuit 1008 and a bias circuit 1006 configured to support the amplified output of power amplifier 1002. Circuity 1000 may be implemented, for example, in device 801 of FIG. 8, where power amplifier 1002 is implemented in power amplifier die 510, subcircuit module 1004 is implemented on submodule PCB 540, single ended output matching circuitry 1008 is implemented in SMD 812, and bias circuit 1006 is implemented in SMD 814.

FIG. 10B is a schematic diagram including a differential output matching circuit according to aspects of the subject technology. FIG. 10B depicts a circuitry 1050 including a power amplifier 1052 and a subcircuit module 1054 having a differential output matching circuit 1058 and a bias circuit 1056 configured to support the amplified output of power amplifier 1052. Circuity 1050 may be implemented, for example, in device 801 of FIG. 8, where power amplifier 1052 is implemented in power amplifier die 510, subcircuit module 1054 is implemented on submodule PCB 540, differential output matching circuitry 1058 is implemented in SMD 812 and a transformer embedded in submodule PCB 540, and bias circuit 1056 is implemented in SMD 814.

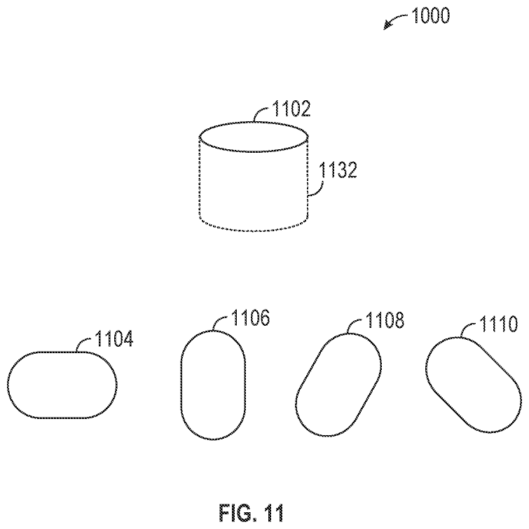

FIG. 11 illustrates a variety conductive joint shapes according to aspects of the subject technology. Joint shapes 1102-1110 indicate a two-dimensional cross section of a joint between primary PCB 520 and submodule PCB 540 of devices 901 and 951 depicted in FIGS. 9A and 9B. Joint shapes 1102-1110 may be a two-dimensional cross section facing primary top surface 529 of primary PCB 520 and/or facing a bottom surface of submodule PCB 540. Joint 1132, such as solder joint 532 (FIG. 9A) or copper pillar 952 (FIG. 9B), may have a round cross section, as in joint shape 1102, or may have a more elongated cross section with various orientations, as in joint shapes 1104-1110. An elongated joint shape selected may reduce the amount area of primary top surface 529 that is required to mount submodule 540 to the primary top surface 529 by selecting a space-efficient orientation for each joint. In other aspects, other non-circular joint shapes not depicted in FIG. 11 may also provide space efficiency. For example, for a particular joint where space is more constrained horizontally but less constrained vertically, an oblong shape that is shorter horizontally and longer vertically such as 1106 may be selected, while for another joint where space is more constrained vertically but less constrained horizontally, an oblong shape oriented such as in 1104 may be selected. Selection of a non-circular joint orientation that reduces PCB surface area requirements may allow an overall size reduction for a system containing a device such as device 901 or 951.

Phrases such as “top” and “bottom” are relative in nature. For example, primary top surface 329 may be relative to various other elements, such as primary bottom surface 323, submodule top surface 341, and top layer 322.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Any of the blocks may be performed simultaneously. In one or more implementations, multitasking and parallel processing may be advantageous.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

A “joint,” as used herein, between two or more elements, may refer to the physical location of a connection between the two or more elements, and/or may refer to the material(s) used to mechanically connect and/or electrically connect the two or more elements. An electrical joint may include material(s) that both mechanically and electrically connect the two or more elements.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, the existence of direct bonding does not exclude other forms of bonding, in which intervening elements may be present.

When an element is referred to herein as being “mounted” to another element, it is to be understood that the elements can be directly mounted to the other element (without any intervening elements) or have intervening elements present between the mounted elements. In contrast, when an element is referred to as being “directly mounted” to another element, it should be understood that no intervening elements are present in the “direct” mounting between the elements. However, the existence of direct mounted does not exclude other forms of mounting, in which intervening elements may be present.

Phrases such as an aspect, the aspect, another aspect, some aspects, one or more aspects, an implementation, the implementation, another implementation, some implementations, one or more implementations, an embodiment, the embodiment, another embodiment, some implementations, one or more implementations, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration.” Any embodiment described herein as “exemplary” or as an “example” is not necessarily to be construed as preferred or advantageous over other implementations. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A device, comprising:
a first printed circuit board (PCB), including a first cavity in a first surface of the first PCB;
a power amplifier mounted in the first cavity; and
a second PCB mounted to the first surface and mounted over the first cavity.

2. The device of claim 1, wherein the power amplifier is configured to amplify radio frequency signals and the device further comprises a first circuit mounted to the second PCB wherein the first circuit is electrically connected to the power amplifier.

3. The device of claim 2, wherein the first circuit includes at least one of:
a bias circuit mounted to the second PCB and electrically connected to the power amplifier;
a single-ended output matching circuit mounted to the second PCB and electrically connected to the power amplifier; and
a differential output matching circuit mounted to the second PCB and electrically connected to the power amplifier.

4. The device of claim 1, wherein the second PCB includes a plurality of insulating layers, and the device further comprises:
passive electric components embedded in the second PCB.

5. The device of claim 1, further comprising:
an electrical joint located on a second surface of the first PCB and at a location on the second surface opposite the power amplifier; and
a via electrically connecting an amplified output from the power amplifier to the electrical joint.

6. The device of claim 1, further comprising:
a second cavity in the first surface of the first PCB; and
a second power amplifier in the second cavity;
wherein the second PCB is mounted over both the first cavity and the second cavity.

7. The device of claim 1, wherein the first PCB is comprised of a plurality of insulating layers, and a depth of the first cavity includes a thickness of at least one of the insulating layers.

8. The device of claim 1, wherein the power amplifier is mounted in the first cavity at a joint between a first surface of the power amplifier and a surface in the first cavity, and the device further comprises:
an electromagnetic coupling shield coupled to a second surface of the power amplifier opposite the first surface of the power amplifier.

9. The device of claim 1, further comprising:
a first mold including a molding material at the first surface of the first PCB, wherein the first mold encloses the second PCB and electrical components mounted to the first surface of the first PCB and the second PCB; and
a second mold including the molding material at a second surface of the first PCB, wherein the second mold encloses electrical components mounted to the second surface of the first PCB.

10. The device of claim 9, further comprising:
an electromagnetic interference (EMI) shield enclosing the first mold, a side surface of the first PCB, and a side surface of the second mold.

11. The device of claim 1, wherein the second PCB is mounted at a joint between the first surface of the first PCB and a second surface of the second PCB, and the device further comprises:
a solder resist layer attached to the second surface of the second PCB and coupled to a first surface of the second PCB opposite the second surface of the second PCB.

12. The device of claim 1, further comprising:
a copper pillar joint between a second surface of the second PCB and the first surface of the first PCB.

13. The device of claim 1, further comprising:
a solder ball joint between a second surface of the second PCB and the first surface of the first PCB; and
a solder resist layer around the solder ball joint.

14. The device of claim 1, further comprising:
a joint between a second surface of the second PCB and the first surface of the first PCB, wherein the joint has a non-circular shape.

15. The device of claim 1, wherein the first PCB includes a second surface opposite the first surface, and the device further comprises:
an array of electrical joints including at least one from a group including: a solder ball grid array, a copper post grid array, a land grid array having an organic solderability preservative finish, and a land grid array with solder mask-defined pads.

16. An device, comprising:
a first printed circuit board (PCB), including a plurality of insulating layers;
a cavity in a first surface of the first PCB, the cavity having a depth from the first surface greater than a thickness of one of the plurality of insulating layers;
a power amplifier mounted at a first electrical joint on a cavity surface in the cavity, wherein the power amplifier is configured to amplify radio frequency signals;
a second electrical joint on a PCB second surface of the first PCB at a location on the PCB second surface opposite the first electrical joint;
a via through one or more of the plurality of insulating layers from the first electrical joint to the second electrical joint and providing an electrical connection path between an amplified output of the power amplifier to the second electrical joint.

17. An device, comprising:
a first printed circuit board (PCB), including a first cavity in a first surface of the first PCB;
a power amplifier mechanically and electrically coupled to an inner surface of the first cavity;
a second PCB mechanically and electrically coupled to the first surface and mounted over the first cavity;
a bias circuit configured to regulate an output of the power amplifier; and
an output matching circuit configured to match the output of the power amplifier to and output device.

18. The device of claim 17, wherein:
the bias circuit is mechanically and electrically coupled to the second PCB; and
the output matching circuit is mechanically and electrically coupled to the second PCB.

19. The device of claim 17, further comprising:
an impedance transformer embedded in the second PCB and configured to match an output of the power amplifier; and
a die shield on the power amplifier configured to limit electromagnetic coupling between the power amplifier and the impedance transformer.

20. The device of claim 17, further comprising:
an electrical joint located on a second surface of the first PCB, wherein the second surface is opposite the first surface and the electrical joint is located on the second surface opposite the power amplifier; and
a via electrically connecting an amplified output from the power amplifier to the electrical joint.
